(19) United States
(12) Patent Application Publication
(10) Pub. No.: US 2007/0243815 A1
(43) Pub. Date: Oct. 18, 2007

(54) Air duct which can be moved vertically and horizontally

(76) Inventor: Vincent Lai, Gueishan Hsiang (TW)

Correspondence Address: PRO-TECHTOR INTERNATIONAL SERVICES, 20775 NORADA CT., SARATOGA, CA, 95070, US

(21) Appl. No.: 11/404,742

(22) Filed: Apr. 14, 2006

(51) Int. Cl. H05K 5/00

(52) U.S. Cl. 454/184

(57) ABSTRACT

An air duct which can be moved vertically and horizontally is the air duct installed on ventholes defined in a side panel of a computer case, and is provided with characteristics that an end of a duct base connected to the air duct is provided with a movable plate which can be extended into slide grooves of a seat frame, that the air duct can be displaced vertically on the seat frame with toothed grooves at two sides of the movable plate and can be also displaced horizontally in slide grooves of an inner frame with toothed grooves at an upper and lower ends of the seat frame, and that the movable air duct device is applicable for use on CPUs disposed at different positions. Moreover, the air duct can be lengthened and shortened on an annular tube of the duct base to accommodate a CPU cooling device of different height.

### BACKGROUND OF THE INVENTION

(a) Field of the Invention

The present invention relates to an air duct, and more particularly to an air duct which can be moved vertically and horizontally to change its position, so as to be in coordination with CPUs (central processing unit) disposed at different positions on different motherboards.

(b) Description of the Prior Art

A conventional heat sink device primarily comprises fins and a fan, wherein the fan is positioned on top of the fins. Wind power from the fan is used to expel heat produced by the CPU (central processor unit). However, the hot air produced by the CPU and peripheral chips circulates within the space interior of a computer case and is unable to be completely expelled. Hence, operators have installed an air duct on a side panel of the computer case. The air duct connects to the CPU disposed on a motherboard, and air from an outer side of the air duct is used to reduce the amount of hot air produced by the CPU. However, air ducts currently on the market are all fixed, unmovable devices, and, because the CPU is disposed at a different position in each personal computer depending on the motherboard used, thus, a fixed type air duct is unable to be used.

### SUMMARY OF THE INVENTION

The main objective of the present invention is to provide an air duct which can be moved vertically and horizontally, wherein the air duct can be displaced in a vertical or horizontal direction at a position of venthole of a computer side panel, so as to be in coordination with CPUs disposed at different positions of all kinds of different motherboards.

To enable a further understanding of said objectives and the technological methods of the invention herein, brief description of the drawings is provided below followed by detailed description of the preferred embodiments.

### BRIEF DESCRIPTION OF THE DRAWINGS

FIG. 1 shows an exterior structural view according to the present invention.

FIG. 2 shows an exploded elevational view according to the present invention.

FIG. 3 shows a front plane view depicting a partial structure according to the present invention.

FIG. 4 shows an exploded elevational view of an air duct and duct base according to the present invention.

FIG. 5 shows an assembled elevational view of the air duct and duct base according to the present invention.

FIG. 6 shows a front plan view of an embodiment according to the present invention.

### DETAILED DESCRIPTION OF THE PREFERRED EMBODIMENTS

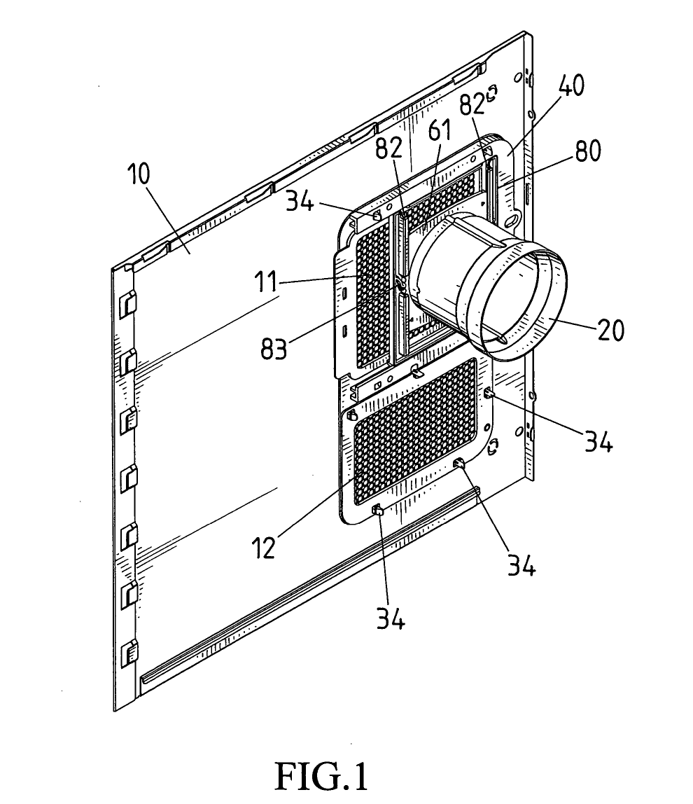

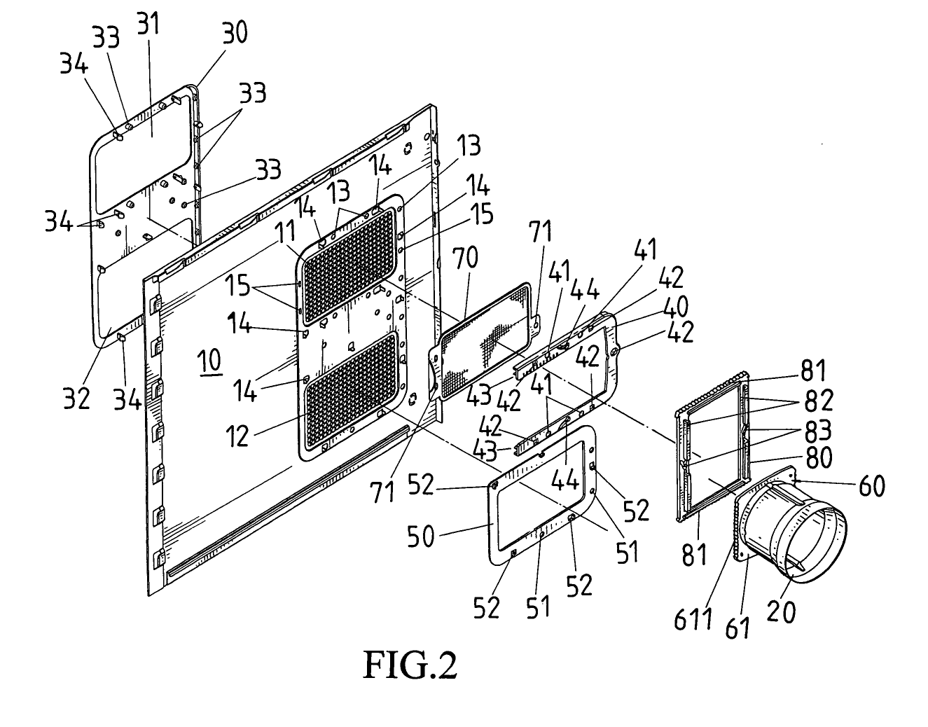

Referring to FIGS. 1 and 2, which shows a movable air duct device of the present invention, wherein two ventholes 11, 12 are defined in a side panel 10 of a computer case. The venthole 11 provides for installing an air duct 20 therein, which connects to a CPU disposed on a motherboard (not shown in the drawings). Air from an outer side of the air duct 20 is used to naturally reduce hot air produced by the CPU. The air duct 20 is movable on the venthole 11, thereby enabling the air duct 20 to function in coordination with CPUs (central processor units) disposed at different positions on different motherboards. The movable air duct device of the present invention comprises an outer frame 30, two inner frames 40, 50 and a duct base 60 having a movable plate 61 connected thereto. The outer frame 30 is positioned on an outer side of the side panel 10. Two through holes 31, 32 are defined in the outer frame 30 corresponding to the ventholes 11, 12 of the side panel 10 respectively. A plurality of insert pieces 33 and hooks 34 are configured on the outer frame 30. The insert pieces 33 and the hooks 34 penetrate a plurality of insert holes 13 and hook holes 14 defined in the side panel 10 respectively. A plurality of insert holes 41, 51 and hook holes 42, 52 are defined in the inner frames 40, 50 respectively, which provide for the insert pieces 33 and the hooks 34 of the outer frame 30 to insert and secure position therein.

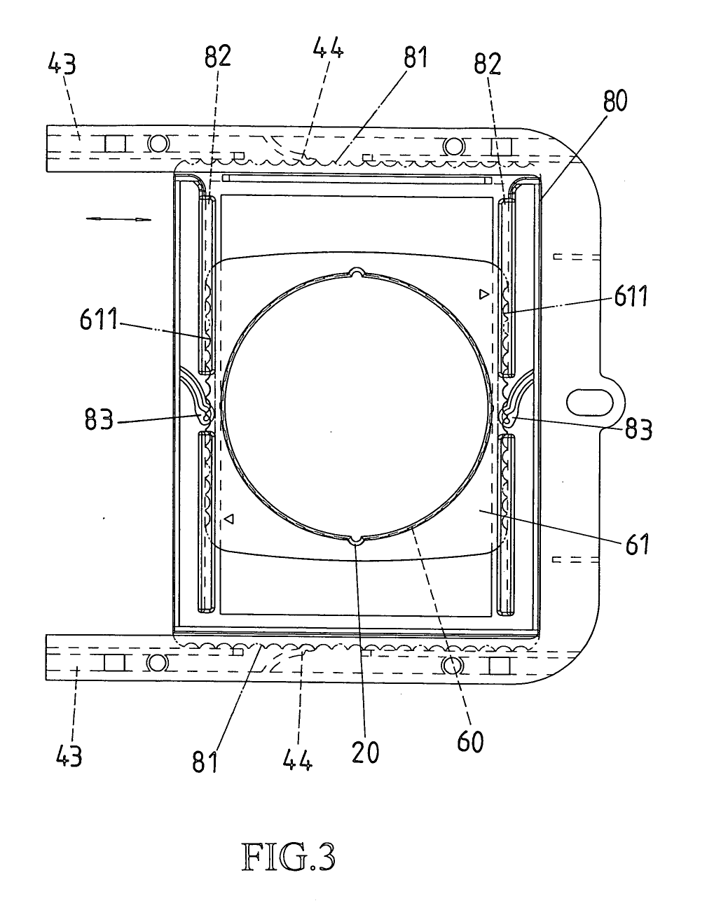

Slide grooves 43 are respectively defined on two sides of an opening of the C-shaped inner frame 40. Referring to FIG. 3, An elastic catch hook 44 is respectively configured within the two slide grooves 43 of the inner frame 40.

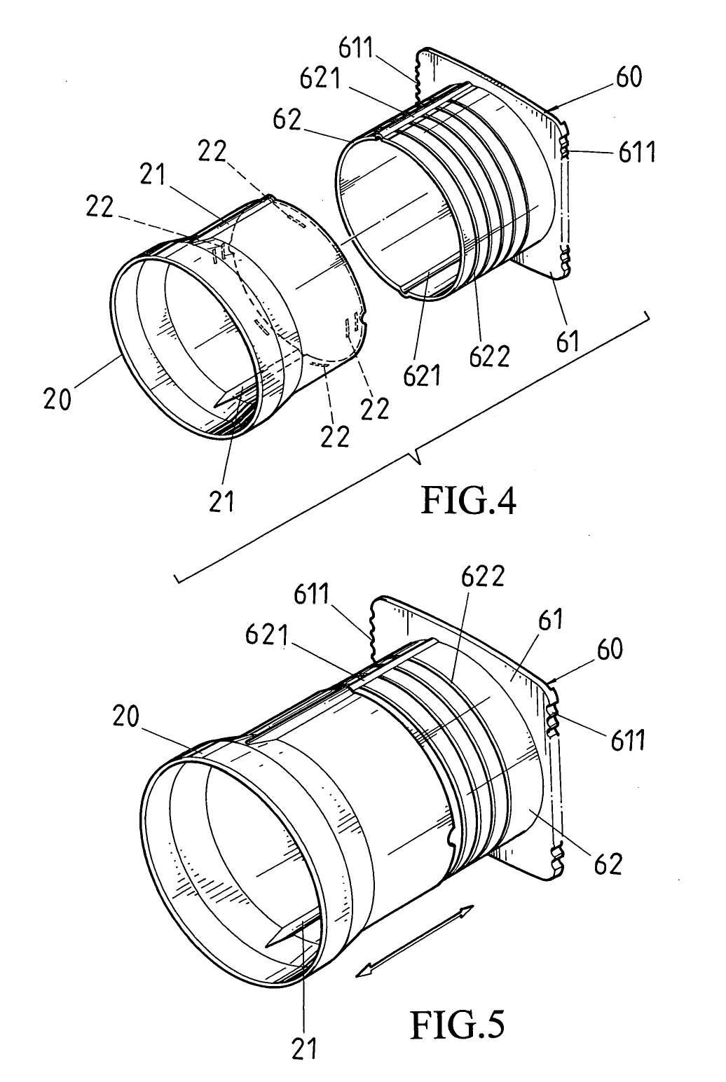

Referring to FIGS. 4 and 5, which show an embodiment of the present invention depicting a structure assembled from the air duct 20 and the duct base 60, wherein two protruding columns 621 and a plurality of annular ringed grooves 622 are configured on an annular tube 62, and two catch grooves 21 are defined on an inner side of the hollow air duct 20, which provide for the protruding columns 621 of the annular tube 62 to respectively clamp therein, thereby enabling the air duct 20 to lengthen and shorten on the annular tube 62. A plurality of catch strips 22 are configured within a front end of the air duct 20, which can clamp within the ringed grooves 622 of the annular tube 62 to secure position thereof. Caliber of the air duct 20 can be adjusted according to a height of CPU cooling device.

Referring to FIGS. 2 and 3, a filter screen 70 can be disposed between the venthole 11 and the duct base 60 to filter out dust. The filter screen 70 is inserted into the slide grooves 43 of the inner frame 40. Location holes 71 respectively defined in a front and rear end of the filter screen 70 provide for location protrusions 15 on the side panel 10 to clamp therein.

The inner frame 40 is installed with a seat frame 80 in a rectangular shape, an upper and lower ends of which are provided with rows of horizontal toothed grooves 81. The seat frame 80 is horizontally moved in the slide grooves 43 of inner frame 40 with the toothed grooves 81, and the catch hook 44 of inner frame 40 can be latched into the toothed grooves 81 of seat frame 80. As the catch hook 44 is provided with elasticity itself, when the seat frame 80 is horizontally displaced by an exerted force, the catch hook 44 will be indented to provide for a displacement of the seat frame 80; on the other hand, when the exerted force is released, the catch hook 44 will then be latched into the toothed grooves 81 for positioning.

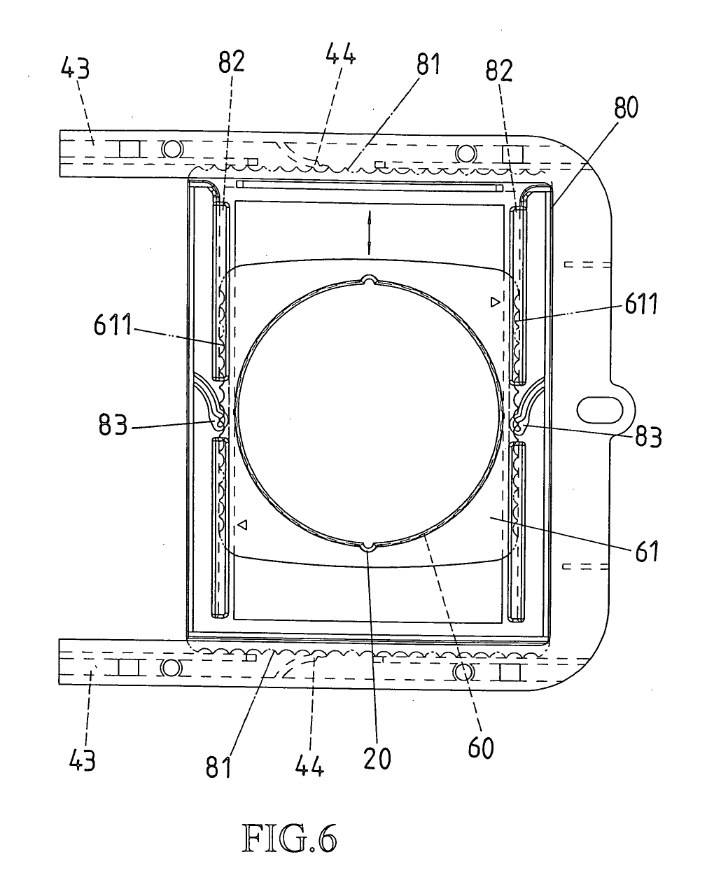

Referring to FIG. 6, a left and a right side of the seat frame 80 are provided with slide grooves 82, respectively. The movable plate 61 of duct base 60 is extended into the seat frame 80 from opening ends of the slide grooves 80, and center sections of the left and right slide grooves 82 are provided with an elastic catch hook 83, respectively. On the other hand, toothed grooves 611 at edges of two sides of movable plate 61 of duct base 60 can provide for a latching of the catch hook 83. When the air duct 20 is moved inside the slide grooves 82 of seat frame 80 with the duct base 60, as the catch hook 83 is provided with elasticity itself, it will be indented to provide for a displacement of the duct base 60 if a force is exerted on the duct base 60 to produce a vertical displacement. On the contrary, when the force exerted on the duct base 60 is released, the catch hook 83 can be latched into the toothed grooves 611 for positioning.

Accordingly, the present invention is to provide the air duct, an orientation of which can be changed vertically and horizontally, depending on a position of CPU disposed on a motherboard. Therefore, it can be applied to CPUs at all kinds of different positions, and its caliber can be adjusted according to a height of CPU cooling device.

It is of course to be understood that the embodiments described herein are merely illustrative of the principles of the invention and that a wide variety of modifications thereto may be effected by persons skilled in the art without departing from the spirit and scope of the invention as set forth in the following claims.

What is claimed is:

1. An air duct which can be moved vertically and horizontally, comprising an air duct installed on ventholes defined in a side panel of a computer case, with the air duct being connected to a CPU (central processing unit) disposed on a motherboard; the air duct device also comprising an outer frame, within which are defined through holes corresponding to the ventholes of the side panel, and a plurality of insert pieces and hooks being configured on the outer frame; an inner frame, on which are defined a plurality of insert holes and hook holes, to provide for the insert pieces and hooks of the outer frame to be securely inserted therein; a duct base, edges of two sides of movable plate at one end of which are provided with toothed grooves, and the other end of which is provided with annular tube, two protruding columns and a plurality of ringed grooves configured on the annular tube, with two catch grooves of an inner side of the air duct providing for the two protruding columns of the annular tube to be clamped therein, and with catch strips of the inner side of the air duct providing for being clamped within the ringed grooves of the annular tube to secure position; a seat frame being installed on the inner frame, an upper and lower ends of which are provided with rows of horizontal toothed grooves, and being moved horizontally in the slide grooves of inner frame with the toothed grooves, with the catch hook of inner frame being able to be latched inside the toothed grooves of seat frame for positioning; a left and right sides of the seat frame being provided with slide grooves for providing an insertion of the movable plate of duct base respectively, and center sections of the slide grooves being provided with elastic catch hooks respectively, which can be latched into the toothed grooves at edges of two sides of the movable plate of duct base for positioning; the air duct assembled from the aforementioned structures being able to be displaced horizontally in the slide grooves of inner frame with the seat frame, and being able to be displaced vertically in the slide grooves of seat frame with the movable plate of duct base.
